(19) United States
(12) Patent Application Publication
(10) Pub. No.: US 2015/0118863 A1
(43) Pub. Date: Apr. 30, 2015

(54) METHODS AND APPARATUS FOR FORMING FLOWABLE DIELECTRIC FILMS HAVING LOW POROSITY

(71) Applicant: Lam Research Corporation, Fremont, CA (US)

(72) Inventors: Megha Rathod, Milpitas, CA (US); Deenesh Padhi, Sunnyvale, CA (US); Nerissa Draeger, Fremont, CA (US); Bart J. van Schravendijk, Palo Alto, CA (US); Kaihan Ashtiani, Cupertino, CA (US)

(21) Appl. No.: 14/519,712

(22) Filed: Oct. 21, 2014

Related U.S. Application Data
(60) Provisional application No. 61/895,883, filed on Oct. 25, 2013.

(51) Int. Cl. H01L 21/02; C23C 16/50; C23C 16/455; C23C 16/52

(52) U.S. Cl. CPC H01L 21/0234; H01L 21/02271; H01L 21/02109; C23C 16/52; C23C 16/50; C23C 16/455
USPC 438/778; 118/697

(57) ABSTRACT

Provided herein are methods and apparatus for forming flowable dielectric films having low porosity. In some embodiments, the methods involve plasma post-treatments of flowable dielectric films. The treatments can involve exposing a flowable film to a plasma while the film is still in a flowable, reactive state but after deposition of new material has ceased.

### CROSS-REFERENCE TO RELATED APPLICATION

This application claims priority to U.S. Provisional Patent Application No. 61/895,883, filed Oct. 25, 2013, which is incorporated by reference herein in its entirety and for all purposes.

### BACKGROUND OF THE INVENTION

It is often necessary in semiconductor processing to fill high aspect ratio gaps with insulating material. This is the case for shallow trench isolation (STI), inter-metal dielectric (IMD) layers, inter-layer dielectric (ILD) layers, pre-metal dielectric (PMD) layers, passivation layers, etc. As device geometries shrink and thermal budgets are reduced, void-free filling of narrow width, high aspect ratio (AR) features (e.g., AR>6:1) becomes increasingly difficult due to limitations of existing deposition processes.

### SUMMARY

One aspect of the subject matter disclosed herein may be implemented in a method of depositing a flowable dielectric film. In some embodiments, the method involves introducing a dielectric precursor and a co-reactant to a deposition chamber housing the substrate under conditions such that a flowable film forms in a gap via a non-plasma-assisted condensation reaction; after forming the flowable film, and while the film is still in a flowable state, stopping a flow of the dielectric precursor to the deposition chamber and exposing the flowable film to a plasma in the deposition chamber.

According to various embodiments, the co-reactant may be an oxidant or a nitridizing agent. In some embodiments, the plasma is generated from a process gas including one or more of hydrogen (H₂), helium (He), nitrogen (N₂) and argon (Ar). Exposure to the plasma may further condensation of the flowable film and/or increase cross-linking of the flowable film. In some embodiments, the plasma is generated from a non-oxidizing process gas. In some embodiments, the exposing the flowable film to a plasma is performed no more than 30 seconds after stopping the flow of the dielectric precursor, or no more than 15 seconds after stopping the flow of the dielectric precursor.

Another aspect of the subject matter disclosed herein may be implemented in a method of depositing a flowable dielectric film. In some embodiments, the method includes flowing a dielectric precursor and a co-reactant to a deposition chamber housing the substrate at substrate temperature of between about −20° C. and 100° C. to thereby form a flowable film in the gap; turning off the flow of the dielectric precursor; and immediately after turning off the flow the dielectric precursor, introducing plasma species to the deposition chamber to thereby expose the flowable film to the plasma species, wherein the substrate temperature is maintained at the deposition temperature.

The method may further include performing a cure operation. Such a cure operation may be performed at a substrate temperature at least about 100° C. greater than the deposition temperature.

Another aspect of the subject matter disclosed herein may be implemented in an apparatus. The apparatus may include a chamber including a substrate support; a plasma generator configured to produce plasma species; one or more inlets to the chamber; and a controller including instructions for: a first operation of introducing a dielectric precursor and a co-reactant to the chamber via the one or more inlets at substrate support temperature of between about −20° C. and 100° C. to thereby form a flowable film; shutting off a flow of the dielectric precursor; and introducing a process gas to the plasma generator no more than 30 seconds after shutting off the dielectric precursor.

These and other aspects are described further below with reference to the drawings.

### BRIEF DESCRIPTION OF DRAWINGS

FIG. 1 is a flow diagram illustrating an example of a process for forming a flowable dielectric film in a gap.

FIGS. 2A-2C show examples of schematic cross-sectional illustrations of substrates including gaps that may be filled with a flowable dielectric film.

FIGS. 3A-3C show examples of schematic depictions of reaction stages in an example of a method of filling a gap with dielectric material.

FIG. 4 is a flow diagram illustrating an example of a process for forming a flowable dielectric film in a gap.

FIG. 5 shows examples of scanning transmission electron microscope (STEM) images of flowable oxide films deposited in trenches with and without plasma post treatment.

FIG. 6 shows examples of electron energy loss spectroscopy (EELS) scan plots comparing the concentration gradients of silicon, oxygen, and carbon in a carbon-doped flowable oxide film in a trench with and without and plasma post-treatment.

FIGS. 7-9 are schematic illustrations of apparatus suitable to practice the methods described herein.

### DETAILED DESCRIPTION OF THE INVENTION

### Introduction

Aspects of the present invention relate to forming flowable dielectric films on substrates. Some embodiments include filling high aspect ratio gaps with insulating material. For ease of discussion, the description below refers chiefly to flowable silicon oxide films, however the processes described herein may also be used with other types of flowable dielectric films. For example, the dielectric film may be primarily silicon nitride, with Si—N and N—H bonds, primarily silicon oxynitride, primarily silicon carbide or primarily silicon oxycarbide films.

It is often necessary in semiconductor processing to fill high aspect ratio gaps with insulating material. This is the case for shallow trench isolation (STI), inter-metal dielectric (IMD) layers, inter-layer dielectric (ILD) layers, pre-metal dielectric (PMD) layers, passivation layers, etc. As device geometries shrink and thermal budgets are reduced, void-free filling of narrow width, high aspect ratio (AR) features becomes increasingly difficult due to limitations of existing deposition processes. In certain embodiments, the methods pertain to filling high aspect (AR) ratio (typically at least 6:1, for example 7:1 or higher), narrow width (e.g., sub-50 nm) gaps. In certain embodiments, the methods pertain to filling low AR gaps (e.g., wide trenches). Also in certain embodiments, gaps of varying AR may be on the substrate, with the embodiments directed at filling low and high AR gaps.

In a particular example, a PMD layer is provided between the device level and the first layer of metal in the interconnect level of a partially fabricated integrated circuit. The methods described herein include dielectric deposition in which gaps, (e.g., the gaps between gate conductor stacks) are filled with dielectric material. In another example, the methods are used for shallow trench isolation processes in which trenches are formed in semiconductor substrates to isolate devices. The methods described herein include dielectric deposition in these trenches. The methods can also be used for back end of line (BEOL) applications, in addition to front end of line (FEOL) applications. These can include filling gaps at an interconnect level.

Vapor-phase reactants are introduced to a deposition chamber to deposit the flowable dielectric films. As-deposited, the flowable dielectric films generally have flow characteristics that can provide consistent fill of a gap, though according to various embodiments, they can be used to deposit overburden layers, blanket layers, and other non-gap fill processes as well as to fill gaps. The term “as-deposited flowable dielectric film” refers to a flowable dielectric film prior to any post-deposition treatments, densification, or solidification. An as-deposited flowable dielectric film may be characterized as a soft jelly-like film, a gel having liquid flow characteristics, a liquid film, or a flowable film.

The flowable dielectric deposition methods described herein are not limited to a particular reaction mechanism; the reaction mechanism may involve an adsorption reaction, a hydrolysis reaction, a condensation reaction, a polymerization reaction, a vapor-phase reaction producing a vapor-phase product that condenses, condensation of one or more of the reactants prior to reaction, or a combination of these. The term flowable dielectric film can include any dielectric film that is formed from vapor-phase reactants and is flowable as-deposited, including films that have been treated such that they are no longer flowable. In some embodiments, the films may undergo a certain amount of densification during the deposition itself.

The as-deposited films can be treated to physically densify and/or chemically convert the as-deposited film to a desired dielectric material. As used herein, the term “densified flowable dielectric film” refers to a flowable dielectric film that has been physically densified and/or chemically converted to reduce its flowability. In some embodiments, the densified flowable dielectric film may be considered to be solidified. In some embodiments, physically densifying the film can involve shrinking the film; according to various embodiments, a densified flowable dielectric film may or may not be shrunk as compared to the as-deposited dielectric film. In some cases physically densifying the film can involve substituting chemicals in the film, which may result in denser, higher volume films.

An example of a post-deposition treatment is an oxidizing plasma that converts the film to an Si—O network and physically densifies the film. In some embodiments, different operations may be performed for conversion and physical densification. Densification treatments may also be referred to as cures or anneals. A post-deposition treatment may be performed in situ in the deposition module, or ex-situ in another module, or in a combination of both. Further description of post-deposition treatment operations is provided below.

Aspects of the invention relate to treatments that reduce porosity of films deposited in gaps. The methods may be employed in accordance with the flowable deposition processes described in the following: U.S. Pat. Nos. 7,074,690; 7,524,735; 7,582,555; 7,629,227; 7,888,273; 8,278,224 and U.S. patent application Ser. Nos. 12/334,726; 12/964,110; 13/315,123; and 13/493,936, all of which are incorporated by reference herein. The treatments, referred to herein as plasma post-treatments, can involve exposing the flowable film to a plasma while the film is still in a flowable, reactive state but after deposition of new material has ceased.

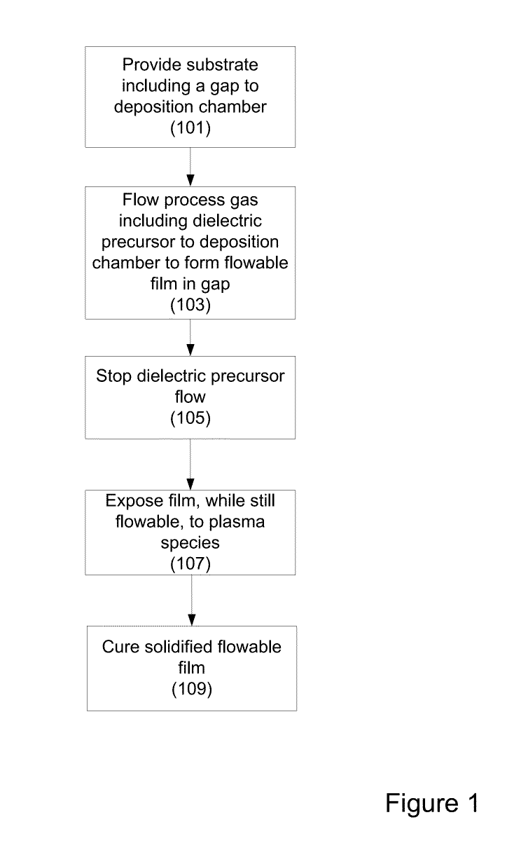

FIG. 1 is a process flow diagram illustrating one example of a process for forming a flowable dielectric film. The process can be used in the fabrication of semiconductor devices, displays, LEDs, photovoltaic panels and the like. As noted above, in semiconductor device fabrication, the process can be used for BEOL applications and FEOL applications. In some embodiments, the process can include applications in which high aspect ratio gaps are filled with insulating material. Examples include shallow trench isolation (STI), formation of inter-metal dielectric (IMD) layers, inter-layer dielectric (ILD) layers, pre-metal dielectric (PMD) layers, and passivation layers, and filling gaps at the interconnect level. Further examples include formation of sacrificial layers for air gap formation or lift-off layers.

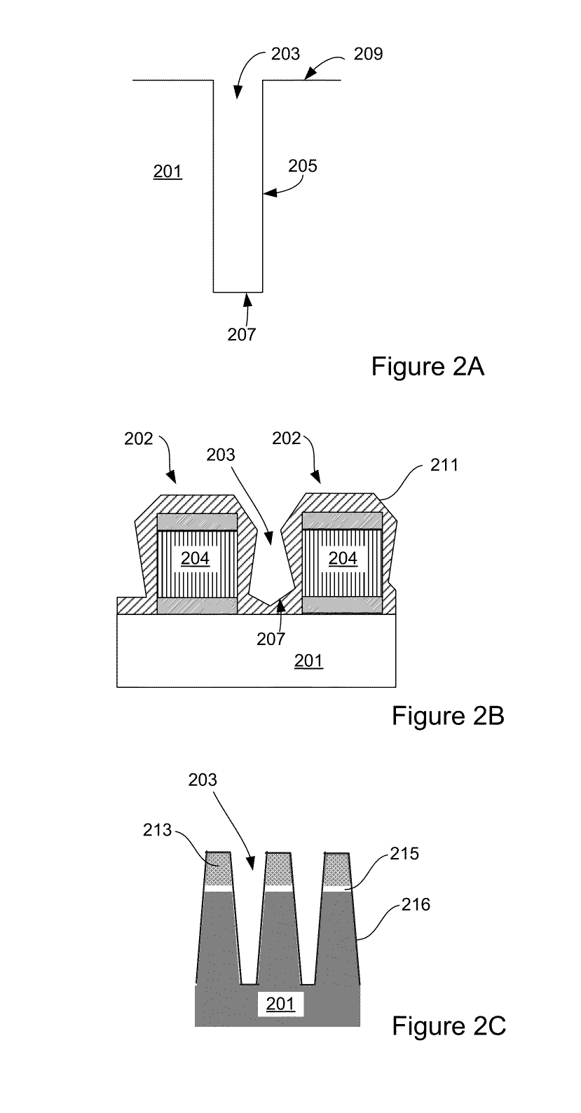

First, a substrate including a gap is provided to a deposition chamber (block 101). Examples of substrates include semiconductor substrates, such as silicon, silicon-on-insulator (SOI), gallium arsenide and the like, as well as glass and plastic substrates. The substrate includes at least one and typically more than one gap to be filled, with the one or more gaps being trenches, holes, vias, etc. FIGS. 2A-2C show examples of schematic cross-sectional illustrations of substrates 201 including gaps 203. Turning first to FIG. 2A, a gap 203 can be defined by sidewalls 205 and a bottom 207. It may be formed by various techniques, depending on the particular integration process, including patterning and etching blanket (planar) layers on a substrate or by building structures having gaps there-between on a substrate. In certain embodiments a top of the gap 203 can be defined as the level of planar surface 209. Specific examples of gaps are provided in FIGS. 2B and 2C. In FIG. 2B, a gap 203 is shown between two gate structures 202 on a substrate 201. The substrate 201 may be a semiconductor substrate and may contain n-doped and p-doped regions (not shown). The gate structures 202 include gates 204 and silicon nitride or silicon oxy-nitride layer 211. In certain embodiments, the gap 203 is re-entrant, i.e., the sidewalls taper inwardly as they extend up from the bottom 207 of the gap; gap 203 in FIG. 2B is an example of a re-entrant gap.

FIG. 2C shows another example of gap to be filled. In this example, gap 203 is a trench formed in silicon substrate 201. The sidewalls and bottom of the gap are defined by liner layer 216, e.g., a silicon nitride or silicon oxynitride layer. The structure also includes pad silicon oxide layer 215 and pad silicon nitride layer 213. FIG. 2C is an example of a gap that may be filled during a STI process. In certain cases, liner layer 216 is not present. In certain embodiments, the sidewalls of silicon substrate 201 are oxidized.

FIGS. 2B and 2C provide examples of gaps that may be filled with dielectric material in a semiconductor fabrication process. The processes described herein may be used to fill any gap that requires dielectric fill. In certain embodiments, the gap critical dimension is the order of about 1-50 nm, in some cases between about 2-30 nm or 4-20 nm, e.g. 13 nm. Critical dimension refers to the width of the gap opening at its narrowest point. In certain embodiments, the aspect ratio of the gap is between 3:1 and 60:1. According to various embodiments, the critical dimension of the gap is 32 nm or below and/or the aspect ratio is at least about 6:1.

As indicated above, a gap typically is defined by a bottom surface and sidewalls. The term sidewall or sidewalls may be used interchangeably to refer to the sidewall or sidewalls of a gap of any shape, including a round hole, a long narrow trench, etc. In some embodiments, the processes described herein may be used to form flowable films on planar surfaces in addition to or instead of in gaps.

Further, in some embodiments, the deposition operations disclosed herein may be performed to seal porous dielectrics. In some such embodiments, operation 103 in FIG. 1 may be a pore sealing operation to seal pores in the porous dielectric. For example, as described in U.S. patent application Ser. No. 14/464,071, which is incorporated by reference herein in its entirety, deposition of a flowable film on an etched ultra-low k (ULK) film may be used to seal pores in the ULK film prior to metallization. In the processes in that application, a flowable dielectric film may be deposited by capillary condensation in the pores.

The deposition surface may be or include one or multiple materials. For example, the sidewall and bottom surfaces that define the gap may be one materials or include multiple materials that can be exposed to the treatment. Referring to FIG. 2C, for example, if a liner layer 216 is present, it may be the only deposition surface. However, if the liner layer 216 is not present, the deposition surface can include the silicon substrate 201, the pad silicon oxide layer 215 and the pad silicon nitride layer 213. Examples of gap sidewall and/or bottom materials include silicon nitrides, silicon oxides, silicon carbides, silicon oxynitrides, silicon oxycarbides, silicides, silicon germanium, as well as bare silicon or other semiconductor material. Particular examples include SiN, SiO₂, SiC, SiON, NiSi, and polysilicon. Further examples of gap sidewall and/or bottom materials used in BEOL processing include copper, tantalum, tantalum nitride, titanium, titanium nitride, ruthenium and cobalt. In certain embodiments, prior to flowable dielectric deposition, the gap is provided with a liner, barrier or other type of conformal layer formed in the gap, such that the deposition surfaces include the conformal layer.

In some embodiments, the deposition surfaces of a substrate are exposed to a treatment. In certain embodiments, one or more substrate surfaces (e.g., a bottom surface of a feature) may be preferentially exposed. If performed, a pre-deposition treatment may be performed in the same or different chamber as the subsequent deposition. In the latter case, the substrate is treated prior to block 101, in the former case, the substrate is treated after block 101 and prior to block 103. Examples of pre-deposition treatments are provided further below.

Returning to FIG. 1, a process gas including a dielectric precursor is flowed into the deposition chamber to form a flowable film in the gap (block 103). In some embodiments, block 103 involves exposing the substrate to gaseous reactants including the dielectric precursor and a co-reactant such that a condensed flowable film forms in the gap. Various reaction mechanisms may take place including one or more of the reaction(s) occurring in the gap and reaction(s) occurring of on field regions with at least some of film flowing into the gap. Examples of deposition chemistries and reaction mechanisms according to various embodiments are described below; however, the methods are not limited to a particular chemistry or mechanism. If depositing a silicon oxide, the dielectric precursor can be a silicon-containing compound and the co-reactant an oxidizing compound such as a peroxide, ozone, oxygen, steam, etc. As described further below, the deposition chemistry may include one or more of a solvent and a catalyst as well. The process gases may be introduced into the reactor simultaneously, or one or more component gases may be introduced prior to the others.

As discussed further below, process conditions in the deposition chamber are maintained such that a flowable film forms in the gap. Example substrate temperatures can be between about −20° C. and 100° C. in certain embodiments, depending on the reactants. Block 103 is generally performed in a non-plasma environment.

The flow of the dielectric precursor is then stopped (105). The flows of the other gases in the process gas may or may not be stopped as well. At this stage, the film is still in a flowable, reactive state, though no additional material is added to the flowable dielectric film.

While the film is still in a flowable reactive state, it is exposed to plasma species (107). In many reaction systems, this means exposing the film to plasma immediately after stopping the flow of the dielectric precursor and/or at the same process conditions such pressure and temperature. This is because any of heating, vacuum, or sitting time can dry the film out. Plasma exposure is effective to remove porosity and densify the flowable film in the gap if the film is still in a flowable state. In some embodiments, the plasma exposure is effective to drive the overall deposition reaction closer to completion to form the flowable film.

The plasma may be generated from a process gas having a primary component of hydrogen (H₂), helium (He), nitrogen (N₂) or argon (Ar). It should be noted that in some instances, an argon-based plasma may sputter the material and may therefore be avoided. In some embodiments, a combination of two or more of these gases may be used.

In some embodiments, block 107 takes place at substantially same substrate temperature as block 103. Block 107 may also take place at substantially the same chamber pressure as block 103. It should be understood that the temperature and/or pressure may fluctuate in the transition from block 103 to block 107, with changing the gas flow into the deposition chamber and introducing a plasma in the chamber. However, the set-point or target temperature may remain substantially same such that the film does not undergo thermal-activated solidification. For example, the target substrate temperature may be within 5° C. of the deposition temperature. Further, it may be possible to drop the pressure to about 0.3 Ton without solidifying the film if the plasma treatment is performed quickly.

In any event, the plasma treatment may be initiated within 30 seconds of stopping the dielectric precursor flow, and in certain embodiments, within 20 seconds or 15 seconds. In many cases, the plasma treatment may be initiated immediately after the flow of the dielectric precursor is stopped, e.g., within 0-5 seconds. In many instances, the film may become less flowable sitting even if held at a constant temperature and pressure after 15-30 seconds, depending on the deposition chamber environment. It should be understood that in some systems, it may be possible to maintain flowability and perform block 107 at a wider range of process conditions and time frames than discussed above.

Block 107 is also generally performed in the deposition chamber itself, to prevent the film from becoming non-flowable during transfer to a separate treatment chamber. Both time and pressure changes that may occur in transferring the substrate to a vacuum transfer chamber or other location may reduce flowability. In some instances, however, it may be possible to transfer the substrate to a separate treatment chamber. For example, a substrate that undergoes deposition at atmospheric pressure may be able to be transferred in atmosphere to a plasma treatment chamber.

Block 107 is distinct from conventional post-deposition cures, which take place at much higher temperatures than the deposition temperatures. As depicted in FIG. 1, in some embodiments, a cure is performed of the now densified flowable film (block 109). The cure may further cross-linking, and remove terminal groups such as —OH and —H groups in the film, and further increase the density and hardness of the film. Depending on the film composition, the cure may also shrink the film. The cure may be performed in in the deposition chamber, or ex-situ in another module, or in a combination of both.

In certain embodiments, a gap is filled via a single cycle, with a cycle including an optional pre-treatment operation and blocks 103-107. In other embodiments, a multi-cycle reaction is performed, with the each cycle including operations 103-107, prior to curing the film. Still further, a multi-cycle reaction may be performed with each cycle including blocks 103-109.

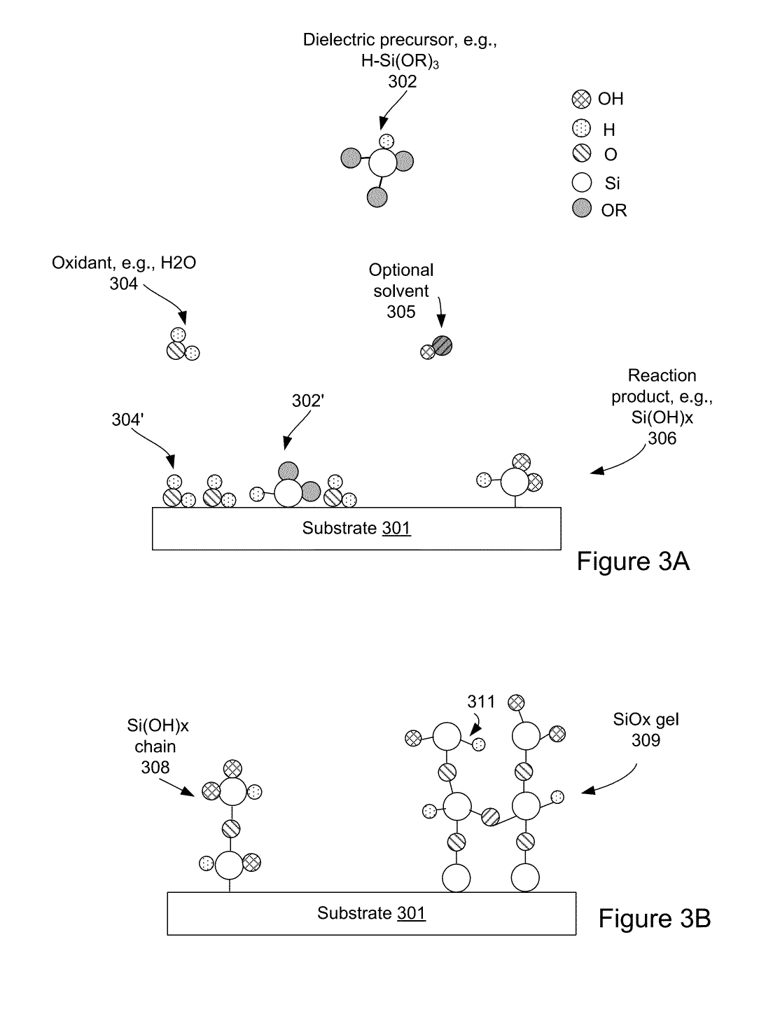

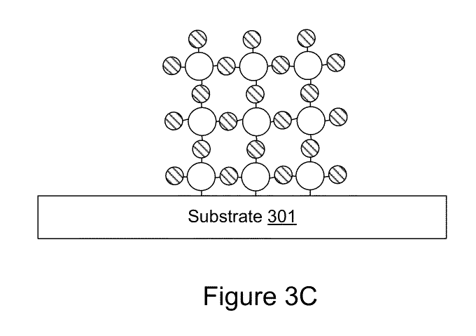

FIG. 3 provides a simplified schematic diagram of an example of a deposition reaction mechanism according to certain embodiments. It should be noted that the methods described herein are not limited to the particular reactants, products and reaction mechanisms depicted, but may be used with other reactants and reaction mechanisms that produce flowable dielectric films. It will also be understood that deposition may involve multiple different concurrent or sequential reaction mechanisms.

FIG. 3A depicts reactant condensation, hydrolysis and initiation of a flowable undoped silica glass (USG) film on a substrate 301. The reactants include a dielectric precursor 302, an oxidant 304, and an optional solvent 305. In some embodiments, an optional catalyst may also be present. The dielectric precursor 302 and oxidant 304 adsorb (condense) on the surface of substrate 301 at 302′ and 304′, respectively. A liquid phase reaction between the dielectric precursor 302′ and oxidant results in hydrolysis of precursor, forming silanols Si(OH)ₓ (306) attached to the wafer surface, thereby initiating the growth of the film. In certain embodiments, the presence of the solvent improves miscibility and surface wettability. Examples of solvents are given further below. FIG. 3B depicts polymerization of the product (see Si(OH)x chain 308) as well as a condensation reaction of the silanols to form crosslinked Si—O chains, with water as a byproduct.

The result of the condensation reaction is a gel 309. At this stage, the organic groups may be substantially eliminated from the gel 309, with alcohol and water released as byproducts, though as depicted Si—H groups 311 remain in the gel as do hydroxyl groups. In some cases, a minute but detectable amount of carbon groups remains in the gel. The overall carbon content may be less than 1% (atomic). In some embodiments, essentially no carbon groups remain, such that Si—C groups are undetectable by FTIR.

In another example of a flowable oxide deposition mechanism to deposit a film having a low dielectric constant (low-k) film, the following reaction may be employed reacting an alkoxysilane dielectric precursor R′—Si(OR)₃ where R′ and R are organic ligands, with R′ an organic ligand incorporated in the low-k film to lower the dielectric constant. Like the mechanism depicted in FIGS. 3A and 3B, it involve hydrolysis of the dielectric precursor by water:

R′—Si(OR)₃+H₂O→R′—Si(OH)₃+ROH (byproduct)

A subsequent condensation and polymerization reaction forms Si—O—Si chains:

R′—Si(OH)₃+R′—Si(OH)₃→R′(OH)ₓSi—O—Si(OH)ₓR′+H₂O (byproduct)

The plasma treatment discussed above with respect to block 107 of FIG. 1 may further the extent of the condensation and polymerization reaction in the gap, thereby reducing porosity. FIG. 3C depicts an example of densified, solidified flowable oxide film 314 after a subsequent cure.

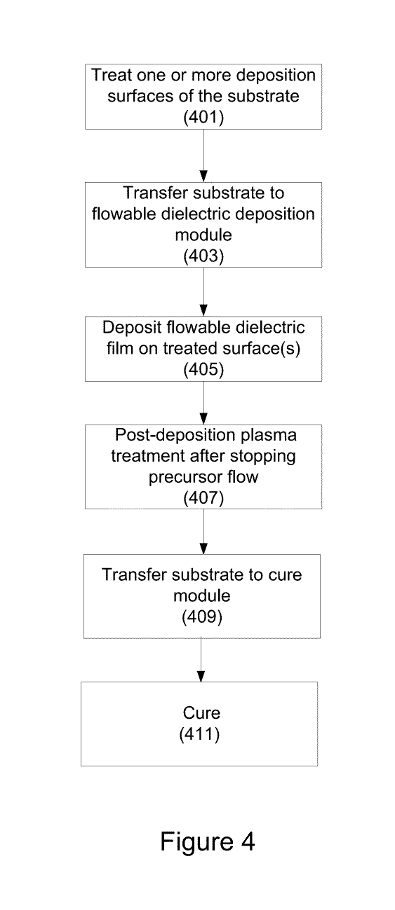

FIG. 4 is a flow diagram illustrating an example of a process including pre-treatment, plasma post-treatment and cure operations. The process begins with treating one or more deposition surfaces (block 401). The substrate is then transferred to a flowable dielectric deposition module (block 403). In some embodiments, the transfer may be under vacuum or inert atmosphere. Examples of inert atmospheres include helium (He), argon (Ar), and nitrogen (N₂). In other embodiments (not depicted), the pre-treatment can be performed in situ in the deposition module and the transfer operation is not required. Once in the deposition module, a flowable dielectric film is deposited to partially fill one or more gaps on the substrate (block 405). An in-situ post-deposition plasma treatment is then performed after stopping the flow of the dielectric precursor as described above (block 407). The substrate is then transferred to a cure module (block 409). The cure module may be the same or a different module as used in operation 401. Further, the process conditions (e.g., treatment type, process gas composition, relative flow rates, power, etc.) may be the same or different than in operation 401. For example, in some implementations, a plasma pre-treatment is performed in a treatment module, with a UV cure performed in a UV cure module.

FIGS. 1 and 4 above provide examples of process flows in accordance with various embodiments. One of ordinary skill in the art will understand that the flowable dielectric deposition methods described herein may be used with other process flows, and that specific sequences as well as the presence or absence of various operations will vary according to implementation.

### Plasma Post-Treatment

Conventional processes for gapfill using flowable dielectric films result in porosity within the trench or other gaps. These processes generally involve deposition followed by a cure operation at a higher temperature. Without being bound by a particular theory, it is believed that the porosity may be due to one or more of the effects described below.

First, it is believed that the reaction may not go to completion throughout the thickness of the film, result in terminal groups that prevent cross-linking For example, the reaction R′—Si(OH)₃+R′—Si(OH)₃→R′(OH)ₓSi—O—Si(OH)ₓR′+H₂O may not go to completion, resulting in higher Si—OH remaining in the film, with Si—OH terminated bonds preventing further cross-linking. Si—OH may be removed during UV cure (or other cure), creating pores. In some embodiments, excess steam or solvent may slow the condensation reaction.

Second, there may be pockets of trapped unreacted reactants or byproducts (e.g., water or alcohol) in the film. The film may condense and form a gel around these molecules before they evaporate. Evaporation out of a trench or other gap is more difficult than evaporation out of a blanket film with high surface area:volume ratio. These molecules will eventually evaporate during the higher temperature cure, leaving pores behind.

Further, shrinkage is difficult in constrained trenches. A flowable film may undergo shrinkage during cure, with the amount of shrinkage depending on the film composition. For example, a film may undergo 1%-25% shrinkage during cure if not constrained in a trench. Shrinking is difficult in constrained trenches: the film either delaminates or the shrinkage does not occur. If the latter, the film remains porous.

Still further, in some implementations, the structure may prevent the cure from reaching or penetrating into trench. In an example, a non-UV transparent polysilicon or metal gate of a PMD structure will prevent non-normal UV flux from reaching the trench, leading to an incomplete cure.

Finally, a cure may remove groups intentionally left in the flowable film during deposition, leaving pores behind. As an example, methyl groups may be incorporated into a low-k film to lower the dielectric constant. However, certain cures may remove at least some of these groups, leaving pores behind.

It should be noted that in conventional processes, a cure may eliminate terminal bonds (such as Si—OH bonds) and to form crosslinked Si—O—Si in a blanket or overburden layer. However, since the elimination of bonds results in shrinkage and shrinkage is non-uniform in a trench, there is a density gradient between film in the trench and overburden layer. In some embodiments, the plasma post treatment described herein helps reduce Si-OH or other terminal bonds for the as-deposited film. Once these bonds are broken, further cross-linking may take place if the film is still reactive and flowable, resulting in greater density and less porosity. The plasma treatment may have one or more of the following benefits: (1) it may supply energy to the film to remove —OH or other groups by thermal means, (2) it may supply radicals which can diffuse into the film and react with the —OH or other groups to break the Si—OH or other bonds, and (3) it may supply ions which can initiate Si—OH bond or other bond breakage. FTIR results show a significant drop in Si—OH content for as-deposited film with plasma treatment as compared to untreated film.

The methods described herein can be used for any type of flowable dielectric process including USG, low-k, and ultra-low k (ULK) flowable oxide. In addition, the methods may be used for deposition of flowable nitrides, carbides, oxynitrides, and oxycarbides. One or more of species (e.g. H₂, N₂, He), gas flows, showerhead gaps, pressure, RF power, and treatment times can be modulated to modulate the intensity and uniformity of the plasma treatment.

As described above, the as-deposited flowable dielectric film is exposed to plasma while it is still in a reactive and flowable state. In many embodiments, to maintain the film in a reactive, flowable state, it cannot be exposed to inert vacuum or elevated temperature and pressure for any significant amount of time (e.g., less than about 30, 15 or even 10 seconds). If the flowable film is held at vacuum with only inert gas flow (no reactants) or if it is exposed to elevated temperature and pressure, then it loses flowability and can no longer be densified in the trench without very aggressive processes that may damage underlying structure materials.

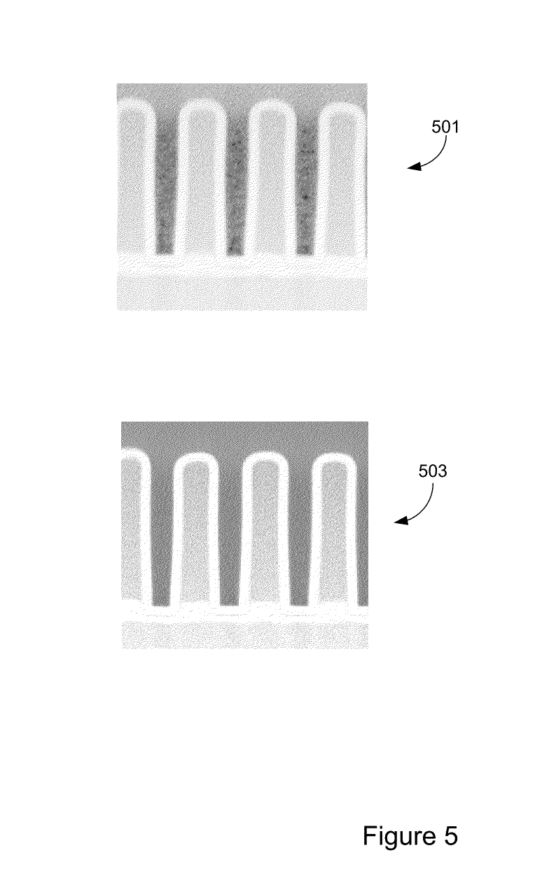

FIG. 5 shows an example of SEM images showing a comparison of flowable oxide film deposited in trenches with and without a hydrogen plasma post treatment. Image 501 shows trenches filled with a carbon-doped flowable oxide film without a plasma post treatment (prior to UV or other cure) and image 503 shows trenches filled with after an in-situ hydrogen plasma post treatment (prior to UV or other cure). Comparing the images shows that the in-situ hydrogen plasma post treatment reduces porosity. A comparison of FTIR spectra for the processes is shown below in Table 1. It can be seen that there is a clear reduction in Si—OH bonding in as-deposited film after post treatment.

| | Difference between no plasma |
|---|---|
| Bond | and plasma post treatment |
| Si—OH (3800-3000 cm⁻¹) | −51% |
| Si—CH₃ (1330-1250 cm⁻¹) | −16% |
| Si—O—Si (1250-970 cm⁻¹) | 9% |
| OH (970-835) | −67% |
| SiCH₃/SiOSi | −23% |
| OH/SiOSi | −70% |
| SiOH/SiOSi | −56% |

The post-deposition plasma treatment may be characterized as a reactive chemical treatment prior to solidification. Once the film solidifies, material (OH and H, for example) in the trench can no longer leave the film. The activated species provided by the plasma prior to solidification allow further reaction in some embodiments.

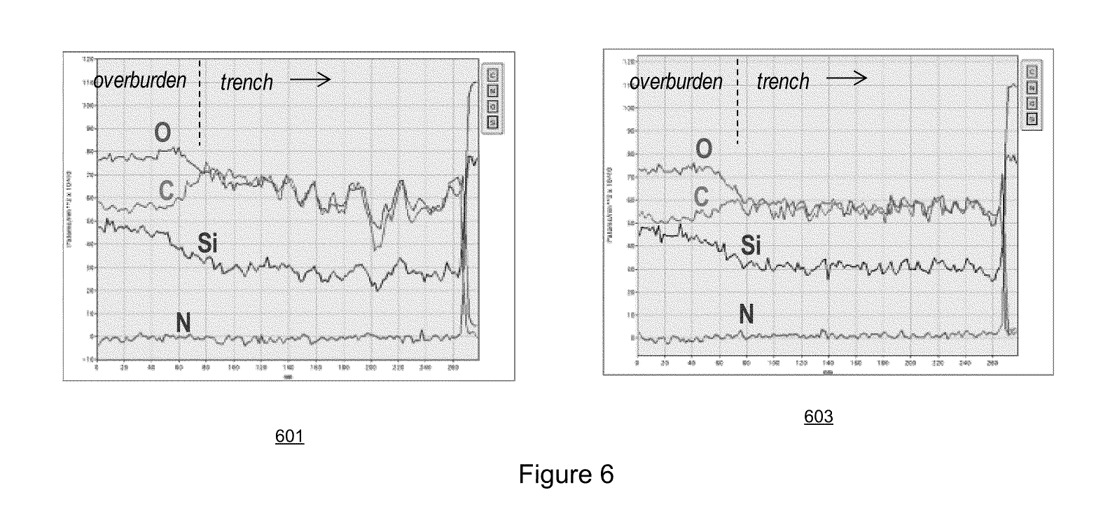

FIG. 6 shows results of an electron energy loss spectroscopy (EELS) scan comparing the concentration gradients of silicon, oxygen, and carbon in a carbon-doped flowable oxide film deposited in a trench with and without and plasma post-treatment. Each scan started from an overburden layer and extended down to the bottom of the feature, with results plotted left to right. Plot 601 shows the results of the as-deposited film without plasma post-treatment and plot 603 shows the results of the as-deposited film following plasma post-treatment. Plasma post-treatment results in a much more uniform concentration throughout the depth of the trench.

### Pre-Treatment

According to various embodiments, a pretreatment operation involves exposure to a plasma containing oxygen, nitrogen, helium or some combination of these. The plasma may be downstream or in-situ, generated by a remote plasma generator, such as an Astron® remote plasma source, an inductively-coupled plasma generator or a capacitively-coupled plasma generator. Examples of pre-treatment gases include O₂, O₃, H₂O, NO, NO₂, N₂O, H₂, N₂, He, Ar, and combinations thereof, either alone or in combination with other compounds. Examples of chemistries include O₂, O₂/N₂, O₂/He, O₂/Ar, O₂/H₂ and H2/He. The particular process conditions may vary depending on the implementation. In alternate embodiments, the pretreatment operation involves exposing the substrate to O₂, O₂/N₂, O₂/He, O₂/Ar or other pretreatment chemistries, in a non-plasma environment. The particular process conditions may vary depending on the implementation. In these embodiments, the substrate may be exposed to the pretreatment chemistry in the presence energy from another energy source, including a thermal energy source, a ultra-violet source, a microwave source, etc. In certain embodiments, in addition to or instead of the pretreatment operations described above, a substrate is pretreated with exposure to a catalyst, surfactant, or adhesion-promoting chemical. The pre-treatment operation, if performed, may occur in the deposition chamber or may occur in another chamber prior to transfer of the substrate to the deposition chamber. Once in the deposition chamber, and after the optional pre-treatment operation, process gases are introduced.

Surface treatments to create hydrophilic surfaces that can be wet and nucleate evenly during deposition are described in concurrently filed U.S. Provisional Patent Application No. 61/895,676, titled “Treatment For Flowable Dielectric Deposition On Substrate Surfaces,” (Attorney Docket No. LAMRP044P), incorporated by reference herein. As described therein, the surface treatments may involve exposure to a remote plasma.

### Deposition Chemistries

For forming silicon oxides, the process gas reactants generally include a silicon-containing compound and an oxidant, and may also include a catalyst, a solvent (and/or other surfactant) and other additives. The gases may also include one or more dopant precursors, e.g., a carbon-, nitrogen-, fluorine-, phosphorous- and/or boron-containing gas. Sometimes, though not necessarily, an inert carrier gas is present. In certain embodiments, the gases are introduced using a liquid injection system. In certain embodiments, the silicon-containing compound and the oxidant are introduced via separate inlets or are combined just prior to introduction into the reactor in a mixing bowl and/or showerhead. The catalyst and/or optional dopant may be incorporated into one of the reactants, pre-mixed with one of the reactants or introduced as a separate reactant. The substrate can be then exposed to the process gases, for example, at block 103 of FIG. 1 or at block 405 of FIG. 4. In some embodiments, conditions in the reactor are such that the silicon-containing compound and the oxidant react to form a condensed flowable film on the substrate. Formation of the film may be aided by presence of a catalyst. The method is not limited to a particular reaction mechanism, e.g., the reaction mechanism may involve a condensation reaction, a vapor-phase reaction producing a vapor-phase product that condenses, condensation of one or more of the reactants prior to reaction, or a combination of these. The substrate is exposed to the process gases for a period sufficient to deposit the desired amount of flowable film. For gapfill, the deposition may proceed long enough to fill at least some of the gap or overfill the gap as desired.

In certain embodiments, the silicon-containing precursor is an alkoxysilane. Alkoxysilanes that may be used include, but are not limited to, the following:
Hₓ—Si—(OR)_{y} where x=0-3, x+y=4 and R is a substituted or unsubstituted alkyl group;
R′ₓ—Si—(OR)_{y} where x=0-3, x+y=4, R is a substituted or unsubstituted alkyl group and R′ is a substituted or unsubstituted alkyl, alkoxy or alkoxyalkane group; and
Hₓ(RO)_{y}—Si—Si—(OR)_{y}Hₓ where x=0-2, x+y=3 and R is a substituted or unsubstituted alkyl group.

Examples of silicon containing precursors include, but are not limited to, alkoxysilanes, e.g., tetraoxymethylcyclotetrasiloxane (TOMCTS), octamethylcyclotetrasiloxane (OMCTS), tetraethoxysilane (TEOS), triethoxysilane (TES), trimethoxysilane (TriMOS), methyltriethoxyorthosilicate (MTEOS), tetramethylorthosilicate (TMOS), methyltrimethoxysilane (MTMOS), dimethyldimethoxysilane (DMDMOS), diethoxysilane (DES), dimethoxysilane (DMOS), triphenylethoxysilane, 1-(triethoxysilyl)-2-(diethoxymethylsilyl)ethane, tri-t-butoxylsilanol, hexamethoxydisilane (HMODS), hexaethoxydisilane (HEODS), tetraisocyanatesilane (TICS), bis-tert-butylamino silane (BTBAS), hydrogen silsesquioxane, tert-butoxydisilane, T8-hydridospherosiloxane, OctaHydro POSS™ (Polyhedral Oligomeric Silsesquioxane) and 1,2-dimethoxy-1,1,2,2-tetramethyldisilane. Further examples of silicon containing precursors include, but are not limited to, silane (SiH₄), disilane, trisilane, hexasilane, cyclohexasilane, and alkylsilanes, e.g., methylsilane, and ethylsilane.

In certain embodiments, carbon-doped silicon precursors are used, either in addition to another precursor (e.g., as a dopant) or alone. Carbon-doped precursors can include at least one Si-C bond. Carbon-doped precursors that may be used include, but are not limited to the, following:
R′ₓ—Si—R_{y} where x=0-3, x+y=4, R is a substituted or unsubstituted alkyl group and R′ is a substituted or unsubstituted alkyl, alkoxy or alkoxyalkane group; and
SiHₓR′_{y}—R_{z} where x=1-3, y=0-2, x+y+z=4, R is a substituted or unsubstituted alkyl group and R′ is a substituted or unsubstituted alkyl, alkoxy or alkoxyalkane group.

Examples of carbon-doped precursors are given above with further examples including, but not being limited to, trimethylsilane (3MS), tetramethylsilane (4MS), diethoxymethylsilane (DEMS), dimethyldimethoxysilane (DMDMOS), methyl-triethoxysilane (MTES), methyl-trimethoxysilane, methyl-diethoxysilane, methyl-dimethoxysilane, trimethoxymethylsilane, (TMOMS), dimethoxymethylsilane, and bis(trimethylsilyl)carbodiimide.

In certain embodiments aminosilane precursors are used. Aminosilane precursors include, but are not limited to, the following:
Hₓ—Si—(NR)_{y} where x=0-3, x+y=4 and R is an organic of hydride group.

Examples of aminosilane precursors are given above, with further examples including, but not being limited to -tert-butylamino silane (BTBAS) or tris(dimethylamino)silane.

Examples of suitable oxidants include, but are not limited to, ozone (O₃), peroxides including hydrogen peroxide (H₂O₂), oxygen (O₂), water (H₂O), alcohols such as methanol, ethanol, and isopropanol, nitric oxide (NO), nitrous dioxide (NO₂) nitrous oxide (N₂O), carbon monoxide (CO) and carbon dioxide (CO₂). In certain embodiments, a remote plasma generator may supply activated oxidant species.

One or more dopant precursors, catalysts, inhibitors, buffers, surfactants, solvents and other compounds may be introduced. In certain embodiments, a proton donor catalyst is employed. Examples of proton donor catalysts include 1) acids including nitric, hydrofluoric, phosphoric, sulphuric, hydrochloric and bromic acids; 2) carboxylic acid derivatives including R—COOH and R—C(═O)X where R is substituted or unsubstituted alkyl, aryl, acetyl or phenol and X is a halide, as well as R—COOC—R carboxylic anhydrides; 3) SiₓX_{y}H_{z} where x=1-2, y=1-3, z=1-3 and X is a halide; 4) RₓSi—X_{y} where x=1-3 and y=1-3; R is alkyl, aloxy, aloxyalkane, aryl, acetyl or phenol; and X is a halide; and 5) ammonia and derivatives including ammonium hydroxide, hydrazine, hydroxylamine, and R—NH₂ where R is substituted or unsubstituted alkyl, aryl, acetyl, or phenol.

In addition to the examples of catalysts given above, halogen-containing compounds which may be used include halogenated molecules, including halogenated organic molecules, such as dichlorosilane (SiCl₂H₂), trichlorosilane (SiCl₃H), methylchlorosilane (SiCH₃ClH₂), chlorotriethoxysilane, chlorotrimethoxysilane, chloromethyldiethoxysilane, chloromethyldimethoxysilane, vinyltrichlorosilane, diethoxydichlorosilane, and hexachlorodisiloxane. Acids which may be used may be mineral acids such as hydrochloric acid (HCl), sulphruic acid (H₂SO₄), and phosphoric acid (H₃PO₄); organic acids such as formic acid (HCOOH), acetic acid (CH₃COOH), and trifluoroacetic acid (CF₃COOH). Bases which may be used include ammonia (NH₃) or ammonium hydroxide (NH₄OH), phosphine (PH₃); and other nitrogen- or phosphorus-containing organic compounds. Additional examples of catalysts are chloro-diethoxysilane, methanesulfonic acid (CH₃SO₃H), trifluoromethanesulfonic acid (“triflic”, CF₃SO₃H), chloro-dimethoxysilane, pyridine, acetyl chloride, chloroacetic acid (CH₂ClCO₂H), dichloroacetic acid (CHCl₂CO₂H), trichloroacetic acid (CCl₂CO₂H), oxalic acid (HO₂CCO₂H), benzoic acid (C₆H₅CO₂H), and triethylamine.

According to various embodiments, catalysts and other reactants may be introduced simultaneously or in particular sequences. For example, in some embodiments, an acidic compound may be introduced into the reactor to catalyze the hydrolysis reaction at the beginning of the deposition process, then a basic compound may be introduced near the end of the hydrolysis step to inhibit the hydrolysis reaction and the catalyze the condensation reaction. Acids or bases may be introduced by normal delivery or by rapid delivery or “puffing” to catalyze or inhibit hydrolysis or condensation reaction quickly during the deposition process. Adjusting and altering the pH by puffing may occur at any time during the deposition process, and difference process timing and sequence may result in different films with properties desirable for different applications. Some examples of catalysts are given above. Examples of other catalysts include hydrochloric acid (HCl), hydrofluoric acid (HF), acetic acid, trifluoroacetic acid, formic acid, dichlorosilane, trichlorosilane, methyltrichlorosilane, ethyltrichlorosilane, trimethoxychlorosilane, and triethoxychlorosilane. Methods of rapid delivery that may be employed are described in U.S. Pat. No. 8,278,224, incorporated by reference herein.

Surfactants may be used to relieve surface tension and increase wetting of reactants on the substrate surface. They may also increase the miscibility of the dielectric precursor with the other reactants, especially when condensed in the liquid phase. Examples of surfactants include solvents, alcohols, ethylene glycol and polyethylene glycol. Difference surfactants may be used for carbon-doped silicon precursors because the carbon-containing moiety often makes the precursor more hydrophobic.

Solvents may be non-polar or polar and protic or aprotic. The solvent may be matched to the choice of dielectric precursor to improve the miscibility in the oxidant. Non-polar solvents include alkanes and alkenes; polar aprotic solvents include acetones and acetates; and polar protic solvents include alcohols and carboxylic compounds.

Examples of solvents that may be introduced include alcohols, e.g., isopropyl alcohol, ethanol and methanol, or other compounds, such as ethers, carbonyls, nitriles, miscible with the reactants. Solvents are optional and in certain embodiments may be introduced separately or with the oxidant or another process gas. Examples of solvents include, but not limited to, methanol, ethanol, isopropanol, acetone, diethylether, acetonitrile, dimethylformamide, and dimethyl sulfoxide, tetrahydrofuran (THF), dichloromethane, hexane, benzene, toluene, isoheptane and diethylether. The solvent may be introduced prior to the other reactants in certain embodiments, either by puffing or normal delivery. In some embodiments, the solvent may be introduced by puffing it into the reactor to promote hydrolysis, especially in cases where the precursor and the oxidant have low miscibility.

Sometimes, though not necessarily, an inert carrier gas is present. For example, nitrogen, helium, and/or argon, may be introduced into the chamber with one of the compounds described above.

As indicated above, any of the reactants (silicon-containing precursor, oxidant, solvent, catalyst, etc.) either alone or in combination with one or more other reactants, may be introduced prior to the remaining reactants. Also in certain embodiments, one or more reactants may continue to flow into the reaction chamber after the remaining reactant flows have been shut off.

Reactions conditions can be such that the silicon-containing compound and oxidant undergo a condensation reaction, condensing on the substrate surface to form a flowable film. The reaction generally takes place in non-plasma conditions prior to the plasma post treatment. As discussed above, in some embodiments, the plasma provides activation to further the reaction and can be generated either remotely or in the deposition chamber.

Chamber pressure may be between about 1 and 200 Torr, in certain embodiments, it is between 10 and 75 Torr. In a particular embodiment, chamber pressure is about 10 Torr.

Partial pressures of the process gas components may be characterized in terms of component vapor pressure and range as follows, with Pp the partial pressure of the reactant and Pvp the vapor pressure of the reactant at the reaction temperature.
Precursor partial pressure ratio (Pp/Pvp)=0.01-1, e.g., 0.01-0.5
Oxidant partial pressure ratio (Pp/Pvp)=0.25-2, e.g., 0.5-1
Solvent partial pressure ratio (Pp/Pvp)=0-1, e.g, 0.1-1

In certain embodiments, the process gas is characterized by having a precursor partial pressure ratio is 0.01 and 0.5, an oxidant partial ratio between 0.5 and 1, and a solvent (if present) partial pressure ratio between 0.1 and 1. In the same or other embodiments, the process gas is characterized by the following:
Oxidant: Precursor partial pressure ratio (Pp_{oxidant}/Pp_{precursor})=0.2-30, e.g., 5-15
Solvent: Oxidant partial pressure ratio (Ppₛₒₗᵥₑₙₜ/Pp_{oxidant})=0-30, e.g., 0.1-5

In certain embodiments, the process gas is characterized by an oxidant: precursor partial pressure ratio of between about 5 and 15 and a solvent:oxidant partial pressure ration of between about 0.1 and 5.

Substrate temperature is between about −20° C. and 100° C. in certain embodiments. In certain embodiments, temperature is between about −20° C. and 30° C., e.g., between −10° C. and 10° C. Pressure and temperature may be varied to adjust deposition time; high pressure and low temperature are generally favorable for quick deposition. High temperature and low pressure will result in slower deposition time. Thus, increasing temperature may require increased pressure. In one embodiment, the temperature is about 5° C. and the pressure about 10 Torr. Exposure time depends on reaction conditions as well as the desired film thickness. Deposition rates are from about 100 angstroms/min to 1 micrometer/min according to various embodiments. In certain embodiments, deposition time is 0.1-180 seconds, e.g., 1-90 seconds.

The substrate is exposed to the reactants under these conditions for a period long enough to deposit a flowable film. The entire desired thickness of film can be deposited in block 103 or 405, if it is a single cycle deposition. In other embodiments that employ multiple deposition operations, only a portion of the desired film thickness is deposited in a particular cycle. According to various embodiments, the substrate can be continuously exposed to the reactants during block 103 or 405, or one or more of the reactants may be pulsed or otherwise intermittently introduced. Also as noted above, in certain embodiments, one or more of the reactants including a dielectric precursor, co-reactant, catalyst or solvent, may be introduced prior to introduction of the remaining reactants.

The flowable film is exposed to a plasma post treatment (see blocks 107 and 407 of FIGS. 1 and 4). Because the treatment is performed while the film is still flowable, it is typically performed in situ in the deposition chamber. Further, it may be performed at the same conditions used during reactant exposure.

Following the plasma post treatment, the film may be cured by purely thermal anneal, exposure to a downstream or direct plasma, exposure to ultraviolet or microwave radiation or exposure to another energy source. Thermal anneal temperatures may be 300° C. or greater (depending on the allowable thermal budget). The treatment may be performed in an inert environment (Ar, He, etc.) or in a potentially reactive environment. Oxidizing environments (using O₂, N₂O, O₃, H₂O, H₂O₂, NO, NO₂, CO, CO₂ etc.) may be used, though in certain situation nitrogen-containing compounds will be avoided to prevent incorporation of nitrogen in the film. In other embodiments, nitridizing environments (using N₂, N₂O, NH₃, NO, NO₂ etc.) can be used and can incorporate a certain amount of nitrogen in the film. In some embodiments, a mix of oxidizing and nitridizing environments are used. Carbon-containing chemistries may be used to incorporate some amount of carbon into the deposited film. According to various embodiments, the composition of the densified film depends on the as-deposited film composition and the treatment chemistry. For example, in certain embodiments, an Si(OH)ₓ as-deposited gel is converted to a SiO network using an oxidizing plasma cure. In other embodiments, an Si(OH)ₓ as-deposited gel is converted to a SiON network. In other embodiments, an Si(NH)ₓ as-deposited gel is converted to an SiON network.

In certain embodiments, the film is cured by exposure to a plasma, either remote or direct (inductive or capacitive). This may result in a top-down conversion of the flowable film to a densified solid film. The plasma may be inert or reactive. Helium and argon plasma are examples of inert plasmas; oxygen and steam plasmas are examples of oxidizing plasmas (used for example, to remove carbon as desired). Hydrogen-containing plasmas may also be used. An example of a hydrogen-containing plasma is a plasma generated from a mix of hydrogen gas (H₂) and a diluent such as inert gas. Temperatures during plasma exposure are typically about 25° C. or higher. In certain embodiments, an oxygen or oxygen-containing plasma is used to remove carbon. In some embodiments, temperature during plasma exposure can be lower, e.g., −15° C. to 25° C.

Temperatures during cures may range from 0-600° C., with the upper end of the temperature range determined by the thermal budget at the particular processing stage. For example, in certain embodiments, the entire process shown in FIG. 1 or FIG. 3 can be carried out at temperatures less than about 400° C. This temperature regime is compatible with NiSi or NiPtSi contacts. In certain embodiments, the temperatures range from about 200° C.-550° C. Pressures may be from 0.1-10 Torr, with high oxidant pressures used for removing carbon.

Other annealing processes, including rapid thermal processing (RTP) may also be used to solidify and shrink the film. If using an ex situ process, higher temperatures and other sources of energy may be employed. Ex situ treatments include high temperature anneals (700-1000° C.) in an environment such as N₂, O₂, H₂O, Ar and He. In certain embodiments, an ex situ treatment involves exposing the film to ultraviolet radiation, e.g., in an ultraviolet thermal processing (UVTP) process. For example, temperatures of 100° C., or above, e.g., 100° C.-400° C., in conjunction with UV exposure may be used to cure the film. Other flash curing processes, including RTP or laser anneal, may be used for the ex situ treatment as well.

In some embodiments, post-deposition treatments can involve partial densification of the deposited flowable film. One example of an integration process including partial densification of a flowable dielectric film is described in U.S. patent application Ser. No. 13/315,123, which is incorporated by reference herein.

The flowable dielectric deposition may involve various reaction mechanisms depending on the specific implementation. Examples of reaction mechanisms in a method of depositing a flowable oxide film according to certain embodiments are described above. It should be noted that while these reaction steps provide a useful framework for describing various aspects of the invention, the methods described herein are not necessarily limited to a particular reaction mechanism.

In some embodiments, the overall deposition process may be described in context of two steps: hydrolysis and condensation. The first step involves hydrolysis of silicon-containing precursors by the oxidant. For example, alkoxy groups (—OR) of the silicon containing precursor may be replaced with hydroxyl groups (—OH). The —OH groups and the residual alkoxy groups participate in condensation reactions that lead to the release of water and alcohol molecules and the formation of Si—O—Si linkages. In this mechanism, the as-deposited film may not have appreciable carbon content even though the alkoxysilane precursor contains carbon. In certain embodiments, reactant partial pressure is controlled to facilitate bottom up fill. Liquid condensation can occur below saturation pressure in narrow gaps; the reactant partial pressure controls the capillary condensation. In certain embodiments, reactant partial pressure is set slightly below the saturation vapor pressure. In a hydrolyzing medium, the silicon-containing precursor forms a fluid-like film on the wafer surface that preferentially deposits in trenches due to capillary condensation and surface tension forces, resulting in a bottom-up fill process.

It should be noted that the methods described herein are not limited to the particular reactants, products and reaction mechanisms described, but may be used with other reactants and reaction mechanisms that produce flowable dielectric films. It will also be understood that deposition and annealing may involve multiple different concurrent or sequential reaction mechanisms.

An example of reactant condensation, hydrolysis and initiation of a flowable dielectric film on a deposition surface follows. The deposition surface is held at a reduced temperature such as −15° C. to 30° C., e.g., −5° C. The reactants include a silicon-containing dielectric precursor, an oxidant, an optional catalyst and an optional solvent. The dielectric precursor absorbs on the surface. A liquid phase reaction between the precursor and oxidant results in hydrolysis of the precursor, forming a product, e.g., silanols Si(OH)ₓ that are attached to the deposition surface, initiating the growth of the film. In certain embodiments, the presence of the solvent improves miscibility and surface wettability.

Polymerization of the product to form, for example, Si(OH)ₓ chains as well as condensation of the product to form, for example, crosslinked Si—O chains can follow. The result of the condensation reaction is an as-deposited dielectric film. At this stage, the organic groups may be substantially eliminated from the film, with alcohol and water released as byproducts, though Si—H groups and hydroxyl groups can remain. In some cases, a minute but detectable amount of carbon groups remains. The overall carbon content may be less than 1% (atomic). In some embodiments, essentially no carbon groups remain, such that Si—C groups are undetectable by FTIR. Continuing the example, the as-deposited film can be annealed in the presence of an activated oxygen species, e.g. oxygen radicals, ions, etc. In certain embodiments, the anneal has two effects: 1) oxidation of the film, to convert SiOH and SiH to SiO; and 2) film densification or shrinkage. The oxygen oxidizes Si—H bonds and facilitates formation of a SiOₓ network with substantially no Si—H groups. The substrate temperature may be raised, e.g., to 375° C. to facilitate film shrinkage and oxidization. In other embodiments, the oxidation and shrinkage operations are carried out separately. In some embodiments, oxidation may occur at a first temperature (e.g., 200° C.) with further densification occurring at a higher temperature (e.g., 375° C.).

In some embodiments, densification may be limited by film constraints: for example, film in a gap can be constrained by the sidewalls and the bottom of the gap, with the top of the gap the only free surface. As the critical dimension decreases, less free surface is available, less relaxation is possible and a crust or high density region formed at the free surface is thinner. In some cases film below a high density region does not densify. While the constraints formed by the sidewalls and crust prevent densification, a reactant can diffuse through the crust, forming low density dielectric film. For example, oxygen species can diffuse, oxidizing the SiOH and SiH groups even without substantial densification. Moreover, as described above with respect to FIGS. 1-6 in embodiments of the invention, a plasma post treatment performed while the film is still flowable reduces porosity and densities films in a gap.

The reaction mechanism described above is but one example of a reaction mechanism that may be used in accordance with the present invention, depending on the particular reactants. For example, in certain embodiments, peroxides are reacted with silicon-containing precursors such as alkylsilanes to form flowable films including carbon-containing silanols. In other embodiments, Si—C or Si—N containing dielectric precursors may be used, either as a main dielectric precursor or a dopant precursor, to introduce carbon or nitrogen in the gel formed by a hydrolysis and condensation reaction as described above. For example, triethoxysilane may be doped with methyl-triethoxysilane (CH₃Si(OCH₂)₃) to introduce carbon into the as-deposited film. Still further, in certain embodiments the as-deposited film is a silicon nitride film, including primarily Si—N bonds with N—H bonds.

In certain embodiments, the flowable dielectric film may be a silicon and nitrogen-containing film, such as silicon nitride or silicon oxynitride. It may be deposited by introducing vapor phase reactants to a deposition chamber at conditions such that they react to form a flowable film. The nitrogen incorporated in the film may come from one or more sources, such as a silicon and nitrogen-containing precursor (for example, trisilylamine (TSA) or disilylamine (DSA)), a nitrogen precursor (for example, ammonia (NH₃) or hydrazine (N₂H₄)), or a nitrogen-containing gas (N₂, NH₃, NO, NO₂, N₂O).

As described above, a flow of a dielectric precursor may be turned off, and while the carbon-containing silanol, silicon and nitrogen-containing film, or other flowable dielectric film is still in a flowable state, a plasma post treatment may be performed to reduce porosity in the gap.

The flowable dielectric film may also be treated to do one of more of the following: chemical conversion of the as-deposited film and densification. The chemical conversion may include removing some or all of the nitrogen component, converting a Si(ON)ₓ film to a primarily SiO network. It may also include removal of one or more of —H, —OH, —CH and —NH species from the film. Such a film may be densified as described above. In certain embodiments, it may be primarily SiN after treatment; or may be oxidized to form a SiO network or a SiON network. Post-deposition conversion treatments may remove nitrogen and/or amine groups. As described above, post-deposition treatment may include exposure to thermal, chemical, plasma, UV, IR or microwave energy.

### Apparatus

The methods of the present invention may be performed on a wide-range of modules. The methods may be implemented on any apparatus equipped for plasma treatment and/or deposition of dielectric film, including HDP-CVD reactors, PECVD reactors, sub-atmospheric CVD reactors, any chamber equipped for CVD reactions, and chambers used for PDL (pulsed deposition layers).

Such an apparatus may take many different forms. Generally, the apparatus will include one or more modules, with each module including a chamber or reactor (sometimes including multiple stations) that house one or more wafers and are suitable for wafer processing. Each chamber may house one or more wafers for processing. The one or more chambers maintain the wafer in a defined position or positions (with or without motion within that position, e.g. rotation, vibration, or other agitation). While in process, each wafer is held in place by a pedestal, wafer chuck and/or other wafer holding apparatus. For certain operations in which the wafer is to be heated, the apparatus may include a heater such as a heating plate. Examples of suitable reactors are the Sequel™ reactor, the Vector™, the Speed™ reactor, and the Gamma™ reactor all available from Lam Research of Fremont, Calif.

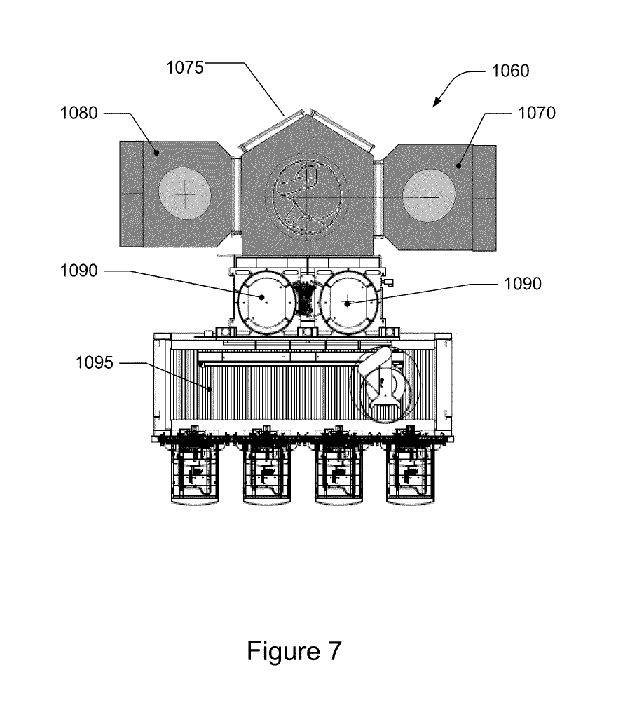

As discussed above, according to various embodiments, the surface treatment may take place in the same or different module as the flowable dielectric deposition. FIG. 7 shows an example tool configuration 1060 including wafer transfer system 1095 and loadlocks 1090, flowable deposition module 1070, and cure module 1080. Additional modules, such as a pre-deposition treatment module, and/or one or more additional deposition modules 1070 or cure modules 1080 may also be included.

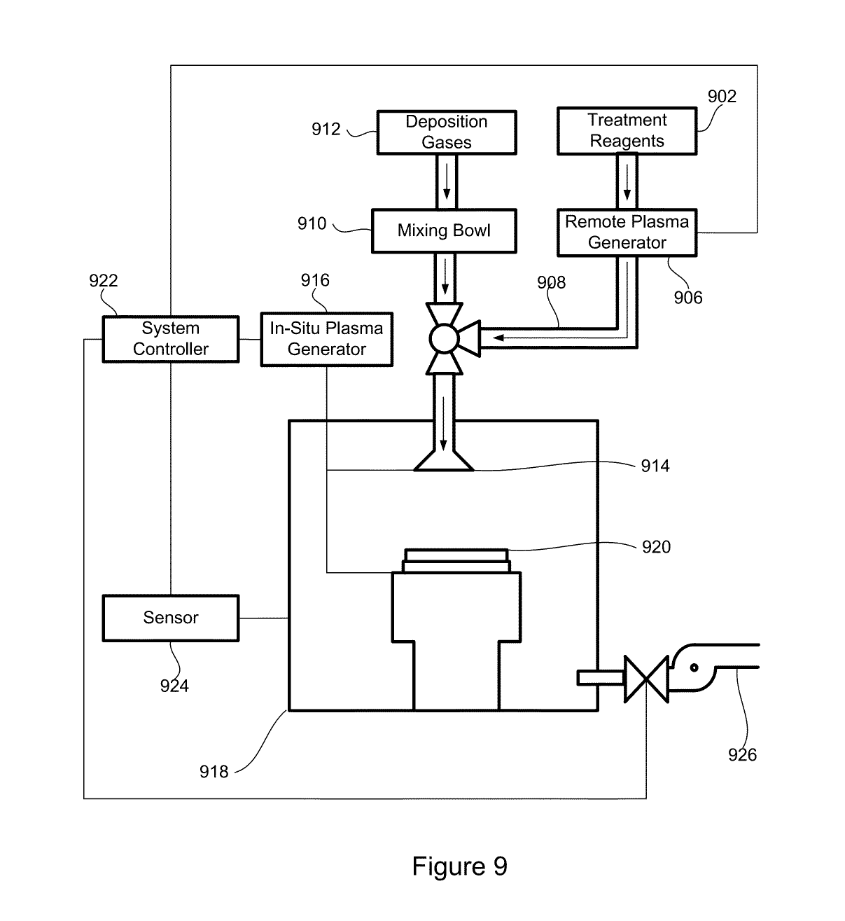

Modules that may be used for pre-treatment or cure include SPEED or SPEED Max, NOVA Reactive Preclean Module (RPM), Altus ExtremeFill (EFx) Module, Vector Extreme Pre-treatment Module (for plasma, ultra-violet or infra-red pre-treatment or cure), SOLA (for UV pre-treatment or cure), and Vector or Vector Extreme modules. These modules may be attached to the same backbone as the flowable deposition module. Also, any of these modules may be on different backbones. A system controller may be connected to any or all of the components of a tool; its placement and connectivity may vary based on the particular implementation. An example of a system controller is described below with reference to FIG. 9.

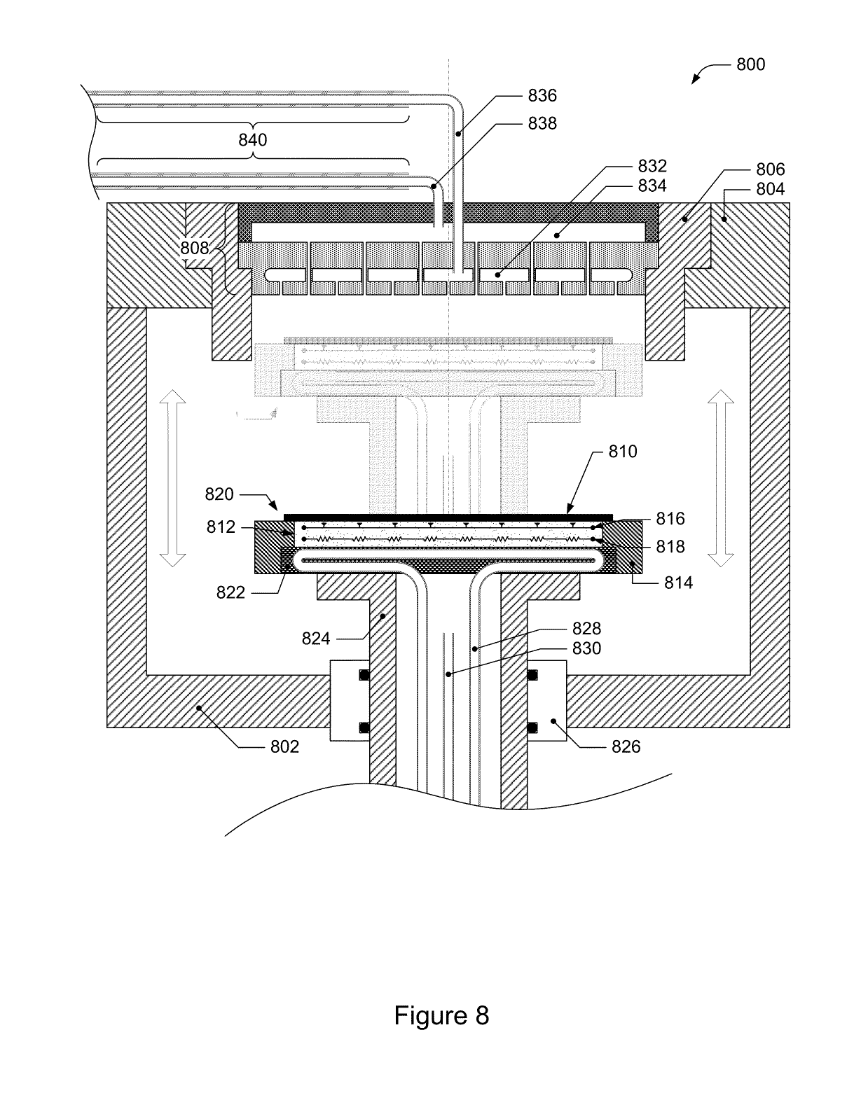

FIG. 8 shows an example of a deposition chamber for flowable dielectric deposition. A deposition chamber 800 (also referred to as a reactor, or reactor chamber) includes chamber housing 802, top plate 804, skirt 806, showerhead 808, pedestal column 824, and seal 826 provide a sealed volume for flowable dielectric deposition. Wafer 810 is supported by chuck 812 and insulating ring 814. Chuck 812 includes RF electrode 816 and resistive heater element 818. Chuck 812 and insulating ring 814 are supported by pedestal 820, which includes platen 822 and pedestal column 824. Pedestal column 824 passes through seal 826 to interface with a pedestal drive (not shown). Pedestal column 824 includes platen coolant line 828 and pedestal purge line 830. Showerhead 808 includes co-reactant-plenum 832 and precursor-plenum 834, which are fed by co-reactant-gas line 836 and precursor-gas line 838, respectively. Co-reactant-gas line 836 and precursor-gas line 838 may be heated prior to reaching showerhead 808 in zone 840. While a dual-flow plenum is described herein, a single-flow plenum may be used to direct gas into the chamber. For example, reactants may be supplied to the showerhead and may mix within a single plenum before introduction into the reactor. 820′ and 820 refer to the pedestal, but in a lowered (820) and raised (820′) position.

The chamber is equipped with, or connected to, gas delivery system for delivering reactants to reactor chamber 800. A gas delivery system may supply chamber 810 with one or more co-reactants, such as oxidants, including water, oxygen, ozone, peroxides, alcohols, etc. which may be supplied alone or mixed with an inert carrier gas. The gas delivery system may also supply chamber with one or more dielectric precursors, for example triethoxysilane (TES), which may be supplied alone or mixed with an inert carrier gas. The gas delivery system is also configured to deliver one or more treatment reagents, for plasma treatment as described herein reactor cleaning For example, for plasma processing, hydrogen, argon, nitrogen, oxygen or other gas may be delivered.

Deposition chamber 800 serves as a sealed environment within which flowable dielectric deposition may occur. In many embodiments, deposition chamber 800 features a radially symmetric interior. Reducing or eliminating departures from a radially symmetric interior helps ensure that flow of the reactants occurs in a radially balanced manner over wafer 810. Disturbances to the reactant flows caused by radial asymmetries may cause more or less deposition on some areas of wafer 810 than on other areas, which may produce unwanted variations in wafer uniformity.

Deposition chamber 800 includes several main components. Structurally, deposition chamber 800 may include a chamber housing 802 and a top plate 804. Top plate 804 is configured to attach to chamber housing 802 and provide a seal interface between chamber housing 802 and a gas distribution manifold/showerhead, electrode, or other module equipment. Different top plates 804 may be used with the same chamber housing 802 depending on the particular equipment needs of a process.

Chamber housing 802 and top plate 804 may be machined from an aluminum, such as 6061-T6, although other materials may also be used, including other grades of aluminum, aluminum oxide, and other, non-aluminum materials. The use of aluminum allows for easy machining and handling and makes available the elevated heat conduction properties of aluminum.

Top plate 804 may be equipped with a resistive heating blanket to maintain top plate 804 at a desired temperature. For example, top plate 804 may be equipped with a resistive heating blanket configured to maintain top plate 804 at a temperature of between −20° C. and 100° C. Alternative heating sources may be used in addition to or as an alternative to a resistive heating blanket, such as circulating heated liquid through top plate 804 or supplying top plate 804 with a resistive heater cartridge.

Chamber housing 802 may be equipped with resistive heater cartridges configured to maintain chamber housing 802 at a desired temperature. Other temperature control systems may also be used, such as circulating heated fluids through bores in the chamber walls.

The chamber interior walls may be temperature-controlled during flowable dielectric to a temperature between −20° C. and 100° C. In some implementations, top plate 804 may not include heating elements and may instead rely on thermal conduction of heat from chamber resistive heater cartridges to maintain a desired temperature. Various embodiments may be configured to temperature-control the chamber interior walls and other surfaces on which deposition is undesired, such as the pedestal, skirt, and showerhead, to a temperature approximately 10° C. to 40° C. higher than the target deposition process temperature. In some implementations, these components may be held at temperatures above this range.

Through actively heating and maintaining deposition chamber 800 temperature during processing, the interior reactor walls may be kept at an elevated temperature with respect to the temperature at which wafer 810 is maintained. Elevating the interior reactor wall temperature with respect to the wafer temperature may minimize condensation of the reactants on the interior walls of deposition chamber 800 during flowable film deposition. If condensation of the reactants occurs on the interior walls of deposition chamber 800, the condensate may form a deposition layer on the interior walls, which is undesirable.

In addition to, or alternatively to, heating chamber housing 802 and/or top plate 804, a hydrophobic coating may be applied to some or all of the wetted surfaces of deposition chamber 800 and other components with wetted surfaces, such as pedestal 820, insulating ring 814, or platen 822, to prevent condensation. Such a hydrophobic coating may be resistant to process chemistry and processing temperature ranges, e.g., a processing temperature range of −20° C. to 100° C. Some silicone-based and fluorocarbon-based hydrophobic coatings, such as polyethylene, may not be compatible with an oxidizing, e.g., plasma, environment and may not be suitable for use. Nano-technology based coatings with super-hydrophobic properties may be used; such coatings may be ultra-thin and may also possess oleophobic properties in addition to hydrophobic properties, which may allow such a coating to prevent condensation as well as deposition of many reactants, used in flowable film deposition. One example of a suitable super-hydrophobic coating is titanium dioxide (TiO₂).

Deposition chamber 800 may also include remote plasma source port, which may be used to introduce plasma process gases into deposition chamber 800. For example, a remote plasma source port may be provided as a means of introducing a treatment gas to the reaction area without requiring that the treatment gas be routed through showerhead 808. In some embodiments, remote plasma species may be routed through the showerhead 808.

In the context of plasma treatment, a direct plasma or a remote plasma may be employed. In the former case, the treatment gas may be routed through the showerhead. Showerhead 808 may include heater elements or heat conduction paths which may maintain the showerhead temperature within acceptable process parameters during processing.

If a direct plasma is to be employed, showerhead 808 may also include an RF electrode for generating plasma environments within the reaction area. Pedestal 820 may also include an RF electrode for generating plasma environments within the reaction area. Such plasma environments may be generated using capacitative coupling between a powered electrode and a grounded electrode; the powered electrode, which may be connected with a plasma generator, may correspond with the RF electrode in showerhead 808. The grounded electrode may correspond with the pedestal RF electrode. Alternative configurations are also possible. The electrodes may be configured to produce RF energy in the 13.56 MHz range, 27 MHz range, or, more generally, between 50 Khz and 60 MHz. In some embodiments, there may be multiple electrodes provided which are each configured to produce a specific frequency range of RF energy. In embodiments wherein showerhead 808 includes a powered RF electrode, chuck 812 may include or act as the grounded RF electrode. For example, chuck 812 may be a grounded aluminum plate, which may result in enhanced cooling across the pedestal-chuck-wafer interface due to aluminum's higher thermal conductivity with respect to other materials, such as ceramics.

FIG. 9 is a schematic illustration of another example of an apparatus 900 suitable to practice the methods of claimed invention. In this example, the apparatus 900 may also be used for flowable dielectric deposition and in situ plasma post treatment. The apparatus 900 includes a processing chamber 918 and a remote plasma generator 906. The processing chamber 918 includes a pedestal 920, a showerhead 914, a control system 922 and other components described below. In the example of FIG. 9, the apparatus 900 also includes a RF generator 916, though this may not be present in some embodiments.

Treatment reagents, such as H₂, He, Ar, N₂, are supplied to the remote plasma generator 906 from various treatment reagent sources, such as source 902. A treatment reagent source may be a storage tank containing one or a mixture of reagents. Moreover, a facility wide source of the reagents may be used.

Any suitable remote plasma generator may be used. For example, a Remote Plasma Cleaning (RPC) units, such as ASTRON® i Type AX7670, ASTRON® e Type AX7680, ASTRON® ex Type AX7685, ASTRON® hf-s Type AX7645, all available from MKS Instruments of Andover, Mass., may be used An RPC unit is typically a self-contained device generating weakly ionized plasma using the supplied cleaning reagents. Imbedded into the RPC unit a high power RF generator provides energy to the electrons in the plasma. This energy is then transferred to the neutral cleaning reagent molecules leading to temperature in the order of 2000K resulting in thermal dissociation of the cleaning reagents. An RPC unit may dissociate more than 90% of incoming cleaning reagent molecules because of its high RF energy and special channel geometry causing the cleaning reagents to adsorb most of this energy.

The treatment reagent mixture is then flown through a connecting line 908 into the processing chamber 918, where the mixture is distributed through the showerhead 914 to treat the wafer or other substrate on the pedestal 920.

The chamber 918 may include sensors 924 for sensing various materials and their respective concentrations, pressure, temperature, and other process parameters and providing information on reactor conditions during the process to the system controller 922. Examples of chamber sensors that may be monitored during the process include mass flow controllers, pressure sensors such as manometers, and thermocouples located in pedestal. Sensors 924 may also include an infra-red detector or optical detector to monitor presence of gases in the chamber. Volatile byproducts and other excess gases are removed from the reactor 918 via an outlet 926 that may include a vacuum pump and a valve.

In certain embodiments, a system controller 922 is employed to control process conditions during the treatment and/or subsequent deposition. The system controller 922 will typically include one or more memory devices and one or more processors. The processor may include a CPU or computer, analog and/or digital input/output connections, stepper motor controller boards, etc. Typically there will be a user interface associated with system controller 922. The user interface may include a display screen, graphical software displays of the apparatus and/or process conditions, and user input devices such as pointing devices, keyboards, touch screens, microphones, etc.

In certain embodiments, the system controller 922 may also control all of the activities during the process, including gas flow rate, chamber pressure, generator process parameters. The system controller 922 executes system control software including sets of instructions for controlling the timing, mixture of gases, chamber pressure, pedestal (and substrate) temperature, and other parameters of a particular process. The system controller may also control concentration of various process gases in the chamber by regulating valves, liquid delivery controllers and MFCs in the delivery system as well as flow restriction valves and the exhaust line. The system controller executes system control software including sets of instructions for controlling the timing, flow rates of gases and liquids, chamber pressure, substrate temperature, and other parameters of a particular process. Other computer programs stored on memory devices associated with the controller may be employed in some embodiments. In certain embodiments, the system controller controls the transfer of a substrate into and out of various components of the apparatuses.

The computer program code for controlling the processes in a process sequence can be written in any conventional computer readable programming language: for example, assembly language, C, C++, Pascal, Fortran or others. Compiled object code or script is executed by the processor to perform the tasks identified in the program. The system software may be designed or configured in many different ways. For example, various chamber component subroutines or control objects may be written to control operation of the chamber components necessary to carry out the described processes. Examples of programs or sections of programs for this purpose include process gas control code, pressure control code, and plasma control code.

The controller parameters relate to process conditions such as, for example, timing of each operation, pressure inside the chamber, substrate temperature, process gas flow rates, RF power, as well as others described above. These parameters are provided to the user in the form of a recipe, and may be entered utilizing the user interface. Signals for monitoring the process may be provided by analog and/or digital input connections of the system controller. The signals for controlling the process are output on the analog and digital output connections of the apparatus.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The disclosed methods and apparatuses may also be implemented in systems including lithography and/or patterning hardware for semiconductor fabrication. Further, the disclosed methods may be implemented in a process with lithography and/or patterning processes preceding or following the disclosed methods. The apparatus/process described hereinabove may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically comprises some or all of the following steps, each step enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

Although the foregoing invention has been described in some detail for purposes of clarity of understanding, it will be apparent that certain changes and modifications may be practiced within the scope of the appended claims. It should be noted that there are many alternative ways of implementing the processes, systems and apparatus of the present invention. Accordingly, the present embodiments are to be considered as illustrative and not restrictive, and the invention is not to be limited to the details given herein.

1. A method of depositing a flowable dielectric film in a gap on a substrate, comprising:
introducing a dielectric precursor and a co-reactant to a deposition chamber housing the substrate under conditions such that a flowable film forms in the gap via a non-plasma-assisted condensation reaction;
after forming the flowable film, and while the film is still in a flowable state, stopping a flow of the dielectric precursor to the deposition chamber and exposing the flowable film to a plasma in the deposition chamber.

2. The method of claim 1, wherein the plasma is generated from a process gas including one or more of hydrogen (H₂), helium (He), nitrogen (N₂) and argon (Ar).

3. The method of claim 1, wherein exposure to the plasma furthers condensation of the flowable film.

4. The method of claim 1, wherein exposure to the plasma increases cross-linking of the flowable film.

5. The method of claim 1, wherein the plasma is generated from a non-oxidizing process gas.

6. The method of claim 1, wherein the co-reactant is an oxidant.

7. The method of claim 1, wherein the co-reactant is nitridizing agent.

8. The method of claim 1, wherein the exposing the flowable film to a plasma is performed no more than 30 seconds after stopping the flow of the dielectric precursor.

9. The method of claim 1, wherein the wherein exposing the flowable film to a plasma is performed no more than 15 seconds after stopping the flow of the dielectric precursor.

10. A method of depositing a flowable dielectric film in a gap on a substrate, comprising:
flowing a dielectric precursor and a co-reactant to a deposition chamber housing the substrate at substrate temperature of between about −20° C. and 100° C. to thereby form a flowable film in the gap;
turning off the flow of the dielectric precursor;
immediately after turning off the flow the dielectric precursor, introducing plasma species to the deposition chamber to thereby expose the flowable film to the plasma species, wherein the substrate temperature is maintained at the deposition temperature.

11. The method of claim 10, further comprising performing a cure operation.

12. The method of claim 11, wherein the cure operation is performed at a substrate temperature at least about 100° C. greater than the deposition temperature.

13. An apparatus comprising:
a chamber including a substrate support;
a plasma generator configured to produce plasma species;
one or more inlets to the chamber; and
a controller comprising instructions for:
a first operation of introducing a dielectric precursor and a co-reactant to the chamber via the one or more inlets at substrate support temperature of between about −20° C. and 100° C. to thereby form a flowable film;
shutting off a flow of the dielectric precursor; and
introducing a process gas to the plasma generator no more than 30 seconds after shutting off the dielectric precursor.

14. The apparatus of claim 13, wherein the controller comprises instructions for introducing the process gas to the plasma generator no more than 15 seconds after shutting off the dielectric precursor.

15. The apparatus of claim 13, wherein the controller comprises instructions for introducing the process gas to the plasma generator immediately after shutting off the dielectric precursor.

16. The apparatus of claim 13, wherein the process gas comprises hydrogen (H₂).
